(19) United States
(12) Patent Application Publication
(10) Pub. No.: US 2012/0320500 A1
(43) Pub. Date: Dec. 20, 2012

(54) PORTABLE ELECTRONIC DEVICE AND METHOD FOR USING THE SAME

(75) Inventors: HOU-HSIEN LEE, Tu-Cheng (TW); CHANG-JUNG LEE, Tu-Cheng (TW); CHIH-PING LO, Tu-Cheng (TW)

(73) Assignee: HON HAI PRECISION INDUSTRY CO., LTD., Tu-Cheng (TW)

(21) Appl. No.: 13/216,271

(22) Filed: Aug. 24, 2011

(30) Foreign Application Priority Data
Jun. 16, 2011 (TW) 100120991

(51) Int. Cl. H05K 7/00

(52) U.S. Cl. 361/679.01

(57) ABSTRACT

A portable electronic device includes a display unit, an image capturing unit, and an image adjusting unit. The image capturing unit captures at least two external images at predetermined times. The at least two external images are compared with each other. In response to the comparison shows that the at least two external images differ from each other, the image adjusting unit corrects a deviation between images displayed by the display unit and a user of the portable electronic device.

### BACKGROUND

1. Technical Field

The present disclosure relates to portable electronic devices, and particularly to a portable electronic device with an e-book reader function and a method for using the same.

2. Description of Related Art

Many portable electronic devices have an e-book reader function. However, most common portable electronic devices lack an anti-shake function when displaying images on displays of the portable electronic devices. When users attempt to read e-books displayed by the portable electronic devices when they are walking or when travelling, viewing experience may be difficult because of shaking of the portable electronic devices, and the eyesight of the users may be adversely affected.

Therefore, there is room for improvement within the art.

### BRIEF DESCRIPTION OF THE DRAWINGS

Many aspects of the present disclosure can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the figures.

FIG. 1 is a schematic view of a portable electronic device, according to an exemplary embodiment.

FIG. 2 is a block diagram of the portable electronic device shown in FIG. 1.

FIG. 3 is a schematic view of displaying an image using the portable electronic device shown in FIG. 1, wherein the portable electronic device is moving up and down relative to a user.

FIG. 4 is a schematic view of displaying an image using the portable electronic device shown in FIG. 1, wherein the portable electronic device is moving left and right relative to a user.

FIG. 5 is a flowchart of a method for using the portable electronic device shown in FIG. 1, according to an exemplary embodiment.

### DETAILED DESCRIPTION

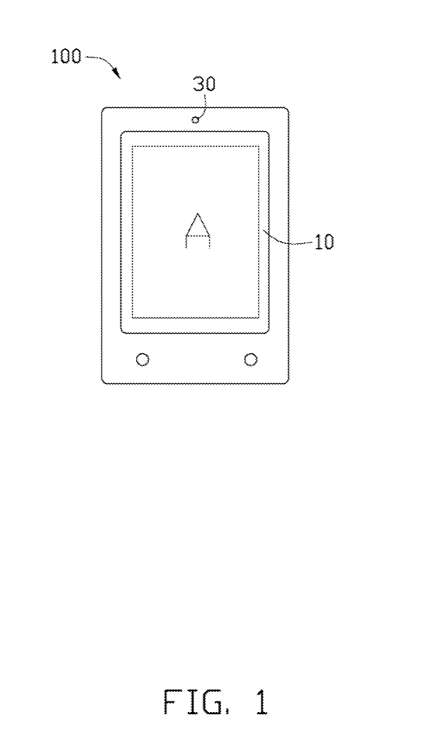

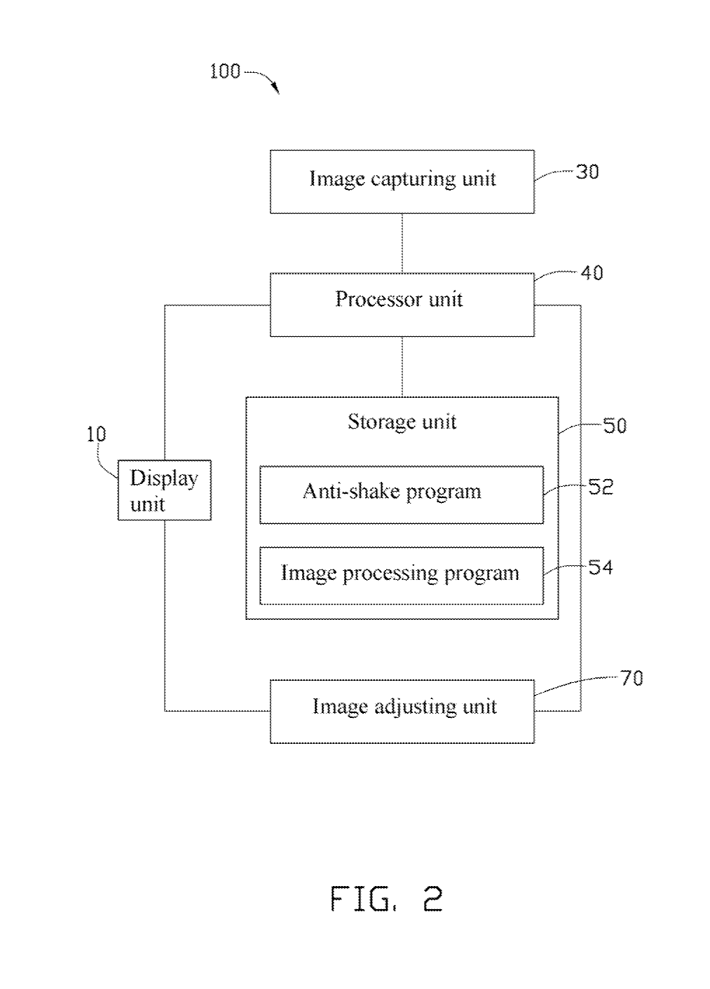

FIG. 1 is a schematic view of a portable electronic device 100, according to an exemplary embodiment. The portable electronic device 100 can be a mobile phone, a personal digital assistant (PDA), a notebook computer, for example. Also referring to FIG. 2, the portable electronic device 100 includes a display unit 10, an image capturing unit 30, a processor unit 40, a storage unit 50, and an image adjusting unit 70.

The display unit 10 is a display device for portable electronic devices. In this embodiment, the display unit 10 is a touch screen. The portable electronic device 100 uses the display unit 10 to display characters and images, such as option menus, messages, and the content of e-books.

The image capturing unit 30 is a built-in digital camera module. The display unit 10 and the image capturing unit 30 are mounted on the same surface of the portable electronic device 100 so faces of users of the portable electronic device 100 are constantly in the view of the image capturing unit 30. In this way, when a user is viewing the display unit 10, the image capturing unit 30 may be controlled to capture images of the user's face.

The processor unit 40 is a central processing unit (CPU). The processor unit 40 is electrically connected to the display unit 10, the image capturing unit 30, and the storage unit 50. The storage unit 50 further stores programs that are configured to reduce the effects of unwanted movement in the portable electronic device 100, such as an anti-shake program 52 and an image processing program 54. When the portable electronic device 100 is turned on, the processor unit 40 automatically runs the anti-shake program 52, and controls the display unit 10 to display an option that allows selection of an anti-shake mode. If the anti-shake mode is selected, the processor unit 40 controls the image capturing unit 30 to capture at least two external images at predetermined times. The images captured by the image capturing unit 30 are received and temporarily stored in the storage unit 50 by the processor unit 40. The processor unit 40 then controls the image processing program 54 to find and isolate images of faces and eyes of users of the portable electronic device 100 in the stored images, and further compares relative positions of the images of the users' faces and eyes in the stored images with each other to detect any movement of the portable electronic device 100 relative to the user.

The image adjusting unit 70 is electrically connected to both the processor unit 40 and the display unit 10. The image adjusting unit 70 includes typical mechanical devices (not shown) for adjusting the display unit 10 and/or electronic devices (not shown), which may include hardware and/or software, for changing the manner in which images are displayed (e.g., image displaying positions) on the display unit 10.

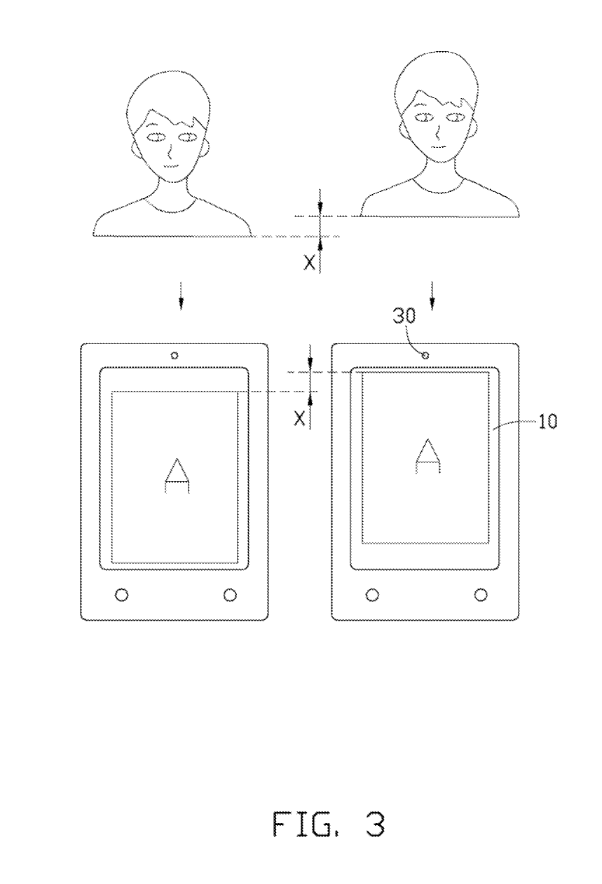

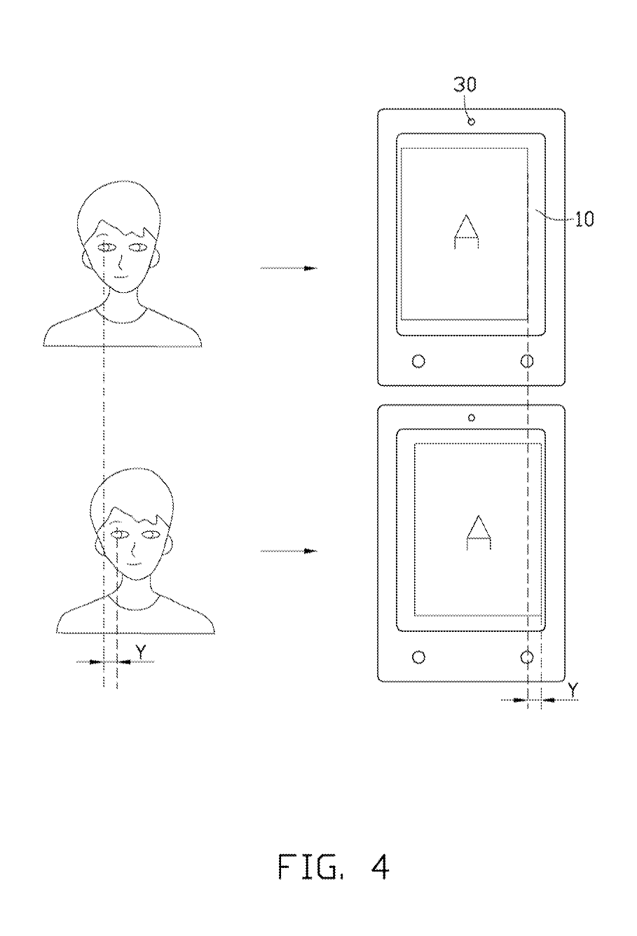

Also referring to FIG. 3 and FIG. 4, when the processor unit 40 detects any movement of the portable electronic device 100 using the face and the eyes of a user as fixed points of reference, the processor unit 40 can control the image adjusting unit 70 to move the display unit 10 (i.e., by mechanical methods) and/or to change image displaying positions on the display unit 10 (i.e., by electronic methods), and thus to maintain the content of the display unit 10 in precisely the same aspect relative to the eyes of the user, so that any physical movements by the portable electronic device 100 become irrelevant. As shown in FIG. 3, if the portable electronic device 100 is moved downwards for distance X relative to the user, or if the face of the user moves upwards for distance X relative to the portable electronic device 100, the processor unit 40 controls the image adjusting unit 70 to move the display unit 10 upwards for distance X, or to move the content of the display unit 10 upwards for distance X. As shown in FIG. 4, if the portable electronic device 100 is moved left for distance Y relative to the user, or if the face of the user moves right for distance Y relative to the portable electronic device 100, the processor unit 40 controls the image adjusting unit 70 to move the display unit 10 for distance Y to the right, or move the content of the display unit 10 for distance Y to the right. In both of the aforementioned situations of FIG. 3 and FIG. 4, the images displayed by the display unit 10 are effectively maintained in their originally viewed positions relative to the user, and the user does not need to take any steps to improve his/her viewing experience.

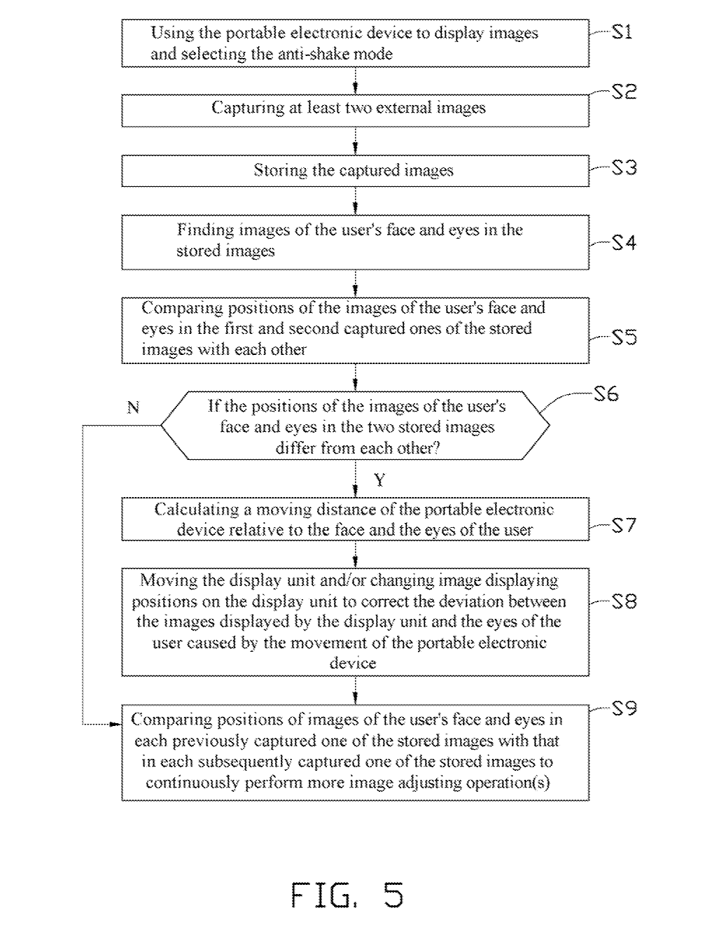

Also referring to FIG. 5, a method for using the portable electronic device 100, according to an exemplary embodiment, is provided. The method includes the steps as follows.

First, the portable electronic device 100 is turned on. A user (e.g., as shown in FIG. 3 and FIG. 4) uses the portable electronic device 100 to display characters and images (e.g., to read e-books or edit messages) on the display unit 10 according to typical methods. At the same time, the processor unit 40 automatically runs the anti-shake program 52, and controls the display unit 10 to display an option for selection of the anti-shake mode of the portable electronic device 100.

When the anti-shake mode is selected (Step S1), the processor unit 40 controls the image capturing unit 30 to capture at least two external images at predetermined times (Step S2). Since the face of the user needs to be in front of the display unit 10 when he/she uses the portable electronic device 100, the images captured by the image capturing unit 30 will include images of the face and eyes of the user.

The processor 40 receives all of the images captured by the image capturing unit 30 and temporarily stores all of the received images in the storage unit 50 (Step S3). All of the images stored in the storage unit 50 are time-stamped.

The processor unit 40 invokes the image processing program 54 to find images of the user's face and eyes in the stored images (Step S4), and compares relative positions of the images of the user's face and eyes in the first and second captured ones of the stored images with each other (Step S5). If the relative positions of the images of the user's face and eyes in the two stored images differ from each other, the processor unit 40 can identify that the portable electronic device 100 has been moved relative to the face and eyes of the user in the period between the capture of the first captured image and the capture of the second captured image (Step S6). By measuring the difference(s) between the relative positions of the images of the user's face and eyes in the first and second captured images, the processor unit 40 can calculate the distance(s) moved by the portable electronic device 100 in relation to the face and the eyes of the user (Step S7).

Once the distance(s) moved by the portable electronic device 100 in relation to the face and the eyes of the user has been determined, the processor unit 40 controls the image adjusting unit 70 to physically move the display unit 10 (i.e., by mechanical methods) and/or change image displaying positions on the display unit 10 (i.e., by electronic methods), as detailed above, and thus corrects any deviation in the aspect of the display unit 10 as seen by the eyes of the user (Step S8). In this way, although the portable electronic device 100 may move relative to the user, the images on the display unit 10 are displayed to precisely suit the eyes of the user. Thus, the user does not need to try and match any physical trembling or instability in the position of the portable electronic device 100. The portable electronic device 100 can be used to view characters and images (e.g., e-books) more easily and the eyesight of users during walking or when travelling in vehicles does not suffer.

The processor unit 40 may control the image capturing unit 30 to capture more than two external images (in the aforementioned Step S2) and stores all of the captured images in the storage unit 50 (in the aforementioned Step S3), in order that, after the aforementioned Step S8, the processor unit 40 can repeatedly perform more image adjusting operation(s) similar to that detailed above (Step S9). That is, the processor unit 40 may further compare the relative positions of the images of the user's face and eyes in the second and third and fourth captured ones of the stored images with each other. If the relative positions of the images of the user's face and eyes in those stored images differ from each other, the processor unit 40 may identify more precisely that the portable electronic device 100 has moved relative to the face and eyes of the user during the interval between the respective capture times of those ones of the stored images. Thus, the processor unit 40 may control the image adjusting unit 70 to further move the display unit 10 physically and/or change image displaying positions on the display unit 10, and thus maintains the aspect of what is being viewed in the eyes of the user despite any movement of the portable electronic device 100. Similarly, the processor unit 40 can compare the relative positions of images of the user's face and eyes in each previously captured one of the stored images with that in each subsequently captured one of the stored images, and continuously correct any deviation from the original viewing aspect, until the image capturing unit 30 is turned off.

When the image adjusting unit 70 moves the display unit 10 physically and/or changes image displaying positions on the display unit 10, the processor unit 40 can cause the image processing program 54 to adjust the lengths, the widths, and the areas of each of the images displayed by the display unit 10, and may change the mode of arranging characters displayed by the display unit 10 (e.g., to change the number of the characters displayed in each row), such that the user can more easily view the images and characters displayed by the display unit 10.

In this embodiment, when the portable electronic device 100 is moved to the left or right relative to the user, the positions of the images of the user's face and eyes in the images captured by the image capturing unit 30 move along the same direction(s) as that of the movement of the portable electronic device 100 relative to the user. To correct any deviation in aspect between the images displayed by the display unit 10 and the eyes of the user, the images displayed by the display unit 10 may be moved on the display unit 10 in a direction(s) which is opposite to that of the movement of the positions of the images of the user's face and eyes in the images captured by the image capturing unit 30. To simplify the calculating processes of the processor unit 40, when the image capturing unit 30 captures external images, the processor unit 40 may cause the image processing program 54 to execute left-right reverses for the images captured by the image capturing unit 30. In this way, when the portable electronic device 100 moves to the left or to the right relative to the user, the positions of the images of the user's face and eyes in the reversed images move in an opposite direction(s). Thus, the content of the display unit 10 can be moved in the same manner as a mirror image relative to the positions of the images of the user's face and eyes in the captured images, to correct any perceived deviation in the content of the display unit 10.

It is to be further understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A portable electronic device, comprising:
a display unit;
a processor unit electrically connected to the display unit;
an image capturing unit electrically connected to the processor; and
an image adjusting unit electrically connected to the processor and the display unit; wherein
the processor unit controls the image capturing unit to capture at least two external images that include at least one object at predetermined times, and compares the at least two external images with each other;
and in response to the comparison shows that positions of the at least one object in the at least two external images differ from each other, the processor unit controls the image adjusting unit to correct a deviation between images displayed by the display unit and a user of the electronic device.

2. The portable electronic device as claimed in claim 1, further comprising a storage unit, the storage unit electrically connected to the processor unit for storing the at least two external images.

3. The portable electronic device as claimed in claim 2, wherein the storage unit includes an anti-shake program; the processor unit controlling the anti-shake program to control the display unit to display an option for selection of an anti-shake mode of the portable electronic device, and controlling the image capturing unit to capture the at least two external images at predetermined times upon selection of the anti-shake mode.

4. The portable electronic device as claimed in claim 2, wherein the storage unit further includes an image processing program, the processor unit controlling the image processing program to find images of a face and eyes of the user in the at least two external images, and comparing positions of the images of the face and the eyes of the user in the at least two external images with each other.

5. The portable electronic device as claimed in claim 4, wherein if the positions of the images of the face and the eyes of the user in the at least two external images differ from each other, the processor unit identifies that the portable electronic device is moved relative to the user, and controls the image adjusting unit to correct a deviation between the images displayed by the display unit and the user caused by the movement of the portable electronic device.

6. The portable electronic device as claimed in claim 5, wherein the processor unit further controls the image processing program to adjust lengths, widths, and areas of the images displayed by the display unit and change arranging modes of characters displayed by the display unit.

7. The portable electronic device as claimed in claim 6, wherein the processor unit further controls the image processing program to execute left-right reverses for the images captured by the image capturing unit.

8. The portable electronic device as claimed in claim 1, wherein the image adjusting unit moves the display unit to correct the deviation between the images displayed by the display unit and the user.

9. The portable electronic device as claimed in claim 1, wherein the image adjusting unit changes image displaying positions on the display unit to correct the deviation between the images displayed by the display unit and the user.

10. A method for using a portable electronic device that includes a display unit, comprising:
displaying images on the display unit and selecting an anti-shake mode of the portable electronic device;
using the portable electronic device to capture at least two external images;
comparing the at least two external images with each other;
if the at least two external images differ from each other, identifying that the portable electronic device is moved relative to a user of the portable electronic device, and calculating a moving distance of the portable electronic device relative to the user; and
correcting the deviation between the images displayed by the display unit and the user caused by the movement of the portable electronic device.

11. The method as claimed in claim 10, further comprising:
finding images of a face and eyes of the user in the at least two external images;
comparing positions of the images of the face and the eyes of the user in the at least two external images with each other; and
if the positions of the images of the face and the eyes of the user in the at least two external images differ from each other, identifying that the portable electronic device is moved relative to the user, and calculating the moving distance of the portable electronic device relative to the user by measuring a difference between the position of the images of the face and the eyes of the user in a previous one of the at least two external images and the position of the images of the face and the eyes of the user in a next one of the at least two external images.

12. The method as claimed in claim 10, wherein the deviation between the images displayed by the display unit and the user caused by the movement of the portable electronic device is corrected by moving the display unit.

13. The method as claimed in claim 10, wherein the deviation between the images displayed by the display unit and the user caused by the movement of the portable electronic device is corrected by changing image displaying positions on the display unit.

14. The method as claimed in claim 10, further comprising storing the at least two external images in the portable electronic device.

15. The method as claimed in claim 10, further comprising adjusting lengths, widths, and areas of the images displayed on the display unit and change arranging modes of characters displayed on the display unit.

16. The method as claimed in claim 10, further comprising executing left-right reverses for the at least two external images.
